(19) United States
(12) Patent Application Publication
(10) Pub. No.: US 2025/0015770 A1
(43) Pub. Date: Jan. 9, 2025

(54) AUDIO AMPLIFIER CIRCUIT

(71) Applicant: ROHM CO., LTD., Kyoto-shi (JP)

(72) Inventor: Mitsuteru SAKAI, Kyoto-shi (JP)

(21) Appl. No.: 18/894,157

(22) Filed: Sep. 24, 2024

Related U.S. Application Data
(63) Continuation of application No. PCT/JP2023/011939, filed on Mar. 24, 2023.

(30) Foreign Application Priority Data
Mar. 30, 2022 (JP) 2022-056803

(51) Int. Cl. H03F 3/217; H03F 1/02; H03F 1/52; H03F 3/213

(52) U.S. Cl. CPC H03F 3/2171; H03F 1/0222; H03F 1/523; H03F 3/213; H03F 2200/03; H03F 2200/372; H03F 2200/441; H03F 2200/444; H03F 2200/474; H03F 2200/522

(57) ABSTRACT

In an audio amplifier circuit, a power supply terminal receives a power supply voltage. A voltage source generates an internal power supply voltage obtained by multiplying the power supply voltage by a first gain and a bias voltage obtained by multiplying the power supply voltage by a second gain. An input gain circuit amplifies an analog audio signal with reference to the bias voltage. The input gain circuit has an input stage and a gain stage. A phase compensation capacitor is connected to the gain stage. A withstand voltage protection circuit clamps an output voltage of the gain stage to a predetermined clamp voltage.

### CROSS REFERENCE TO PRIOR APPLICATIONS

This application is a continuation under 35 U.S.C. § 120 of PCT/JP2023/011939, filed Mar. 24, 2023, which is incorporated herein by reference, and which claimed priority to Japanese Application No. 2022-056803, filed Mar. 30, 2022. The present application likewise claims priority under 35 U.S.C. § 119 to Japanese Application No. 2022-056803, filed Mar. 30, 2022, the entire content of which is also incorporated herein by reference.

### BACKGROUND

### 1. Technical Field

The present disclosure relates to an audio circuit.

### 2. Description of the Related Art

An in-vehicle audio system or a car navigation system includes an audio circuit. A class-D amplifier capable of a highly efficient operation may be used for an amplification stage of the audio circuit.

FIG. 1 is a simplified block diagram of a class-D audio amplifier circuit 1. The class-D audio amplifier circuit 1 has a two-stage configuration including a first stage including an input gain circuit 10 and a subsequent stage including a PWM circuit 20, a driver circuit 30, and an output stage 40. The output stage 40 is connected to a speaker 3 via a filter 2. The PWM circuit 20 includes an integrator 22, an oscillator 24, and a PWM comparator 26.

It is assumed that the input gain circuit 10 in the previous stage includes a 5V element. This means that the amplitude of an output signal of the input gain circuit 10 is 5 V at the maximum, and that the gain of the input gain circuit 10 is low. The integrator 22 of the PWM circuit 20 includes an operational amplifier OA1, resistors Ri and Rfb, and a capacitor Cfb. Since the capacitor Cfb cannot be made large due to restrictions on a capacitance value of a capacitor that can be built in LSI, it is necessary to increase resistance values of the resistors Ri and Rfb. For this reason, a thermal noise of the resistor having a large resistance value becomes dominant, and it becomes difficult to reduce a noise.

The gain of the integrator 22 needs to be determined according to a withstand voltage (5 V) of a previous stage block and a power supply voltage V_{CC}. When the gain of the input gain circuit 10 is small, it is necessary to increase the gain of the integrator 22. That is, the thermal noise of the resistors Ri and Rfb is amplified by the integrator 22. Patent Literature 1 (Japanese Patent Application (Laid Open) No. 2021-072551) proposes a method of improving characteristics by increasing a withstand voltage at a previous stage of an integrator.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a simplified block diagram of a class-D audio amplifier circuit;

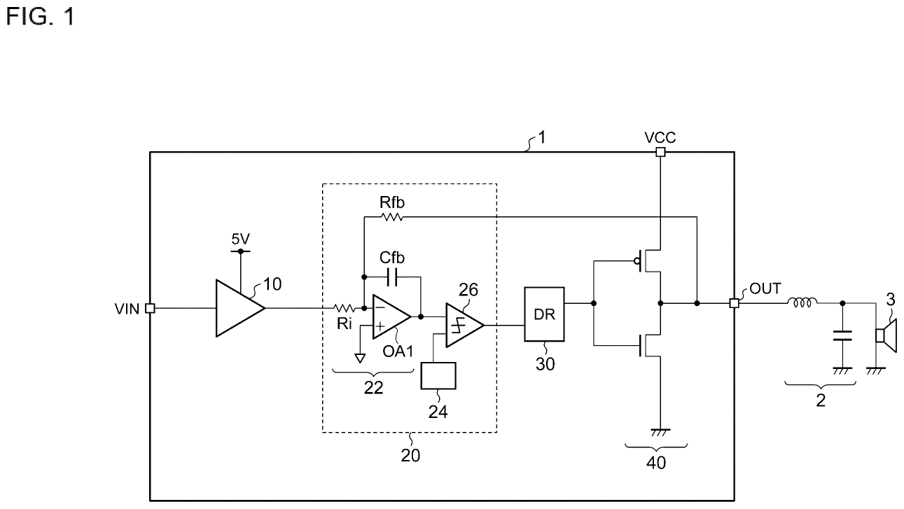

FIG. 2 is a circuit diagram of an in-vehicle audio system including an audio amplifier circuit according to a first embodiment,

FIG. 3 is a diagram illustrating input/output characteristics of a voltage source,

FIG. 4 is a diagram illustrating a level diagram of the in-vehicle audio system of FIG. 2,

FIG. 5 is a diagram illustrating a level diagram of an input gain circuit in the first embodiment,

FIG. 6 is a circuit diagram illustrating a first configuration example of an operational amplifier and a withstand voltage protection circuit,

FIG. 7 is a circuit diagram illustrating a second configuration example of the operational amplifier and the withstand voltage protection circuit,

FIG. 8 is a diagram illustrating a level diagram of an input gain circuit in a second embodiment,

FIG. 9 is a circuit diagram illustrating a third configuration example of the operational amplifier and the withstand voltage protection circuit,

FIG. 10 is a circuit diagram illustrating a fourth configuration example of the operational amplifier and the withstand voltage protection circuit,

FIG. 11 is a circuit diagram illustrating a configuration example of the voltage source; and

FIG. 12 is a circuit diagram of an audio amplifier circuit according to a modification.

### DETAILED DESCRIPTION

### Outline of Embodiments

An outline of some exemplary embodiments of the present disclosure will be described. This outline describes some concepts of one or more embodiments in a simplified manner for the purpose of basic understanding of the embodiments as a prelude to the detailed description below and does not limit the breadth of the invention or disclosure. This outline is not a comprehensive outline of all possible embodiments and is not intended to identify important elements of all embodiments or delineate the scope of some or all embodiments. For convenience, “one embodiment” may be used to refer to one embodiment (example or modification) or a plurality of embodiments (examples or modifications) disclosed in the present specification.

An audio amplifier circuit according to one embodiment includes: a power supply terminal receiving a power supply voltage; a voltage source having a power supply node to which the power supply voltage is supplied and generating an internal power supply voltage obtained by multiplying the power supply voltage by a first gain and a bias voltage V_{FIL} obtained by multiplying the power supply voltage by a second gain; an input gain circuit having a power supply node to which the internal power supply voltage is supplied and amplifying an analog audio signal with reference to the bias voltage V_{FIL}; a pulse modulator having a power supply node to which the internal power supply voltage is supplied and generating a pulse signal having a pulse width according to an output signal of the input gain circuit; and a driver amplifying the pulse signal. The input gain circuit includes an operational amplifier having an input stage and a gain stage, a phase compensation capacitor connected to the gain stage, and a withstand voltage protection circuit structured to clamp an output voltage of the gain stage to a predetermined clamp voltage V_{CL}.

In this embodiment, the input gain circuit includes an element having a withstand voltage higher than 5 V, and the amplitude of the output signal of the input gain circuit is sufficiently large. As a result, a gain of an integrator can be reduced, and a thermal noise can be reduced. On the other hand, when the amplitude of the output signal of the input gain circuit increases, the withstand voltage of the phase compensation capacitor becomes a problem. Therefore, the phase compensation capacitor can be protected by adding the withstand voltage protection circuit having the clamp voltage V_{CL} according to the withstand voltage of the phase compensation capacitor. In addition, by appropriately setting the bias voltage V_{FIL}, the amplitude of the output signal of the input gain circuit can be increased within a range of the withstand voltage of the phase compensation capacitor.

In one embodiment, the input stage may have a P-type input. The withstand voltage protection circuit may clamp the output voltage of the gain stage so as not to exceed the clamp voltage V_{CL}.

In one embodiment, when a is set to a constant satisfying 0.9≤α≤1.1, V_{FIL}=α×V_{CL} may be satisfied.

In one embodiment, the clamp voltage V_{CL} may be a voltage obtained by level-shifting the bias voltage V_{FIL} to the high potential side. The withstand voltage protection circuit may sink an electric current from the output node of the gain stage when the output voltage of the gain stage exceeds the clamp voltage V_{CL}.

In one embodiment, the withstand voltage protection circuit may include: a current source; a first transistor having a control electrode receiving the bias voltage V_{FIL} and a first electrode connected to a ground; a resistor connected to a second electrode of the first transistor; and a current mirror circuit including an input transistor and an output transistor, in which the input transistor is inserted between the resistor and the current source, and the output transistor is connected to the output node of the gain stage.

The withstand voltage protection circuit may include a zener diode connected between a ground line and the output node of the gain stage.

In one embodiment, the input stage may have an N-type input. The withstand voltage protection circuit may clamp the output voltage of the gain stage so as not to fall below the clamp voltage.

In one embodiment, when β is set to a constant satisfying 0.9≤β≤1.1, V_{FIL}=V_{REGA}−β×V_{CL} may be satisfied.

In one embodiment, the clamp voltage V_{CL} may be a voltage obtained by level-shifting the bias voltage V_{FIL} to the low potential side. The withstand voltage protection circuit may source a current to the output node of the gain stage when the output voltage of the gain stage falls below the clamp voltage V_{CL}.

In one embodiment, the withstand voltage protection circuit may include: a power supply node structured to receive the internal power supply voltage; a current source; a first transistor having a control electrode receiving the bias voltage V_{FIL} and a first electrode connected to the power supply node; a resistor connected to a second electrode of the first transistor; and a current mirror circuit including an input transistor and an output transistor, in which the input transistor is inserted between the resistor and the current source, and the output transistor is connected to an output node of the gain stage.

In one embodiment, the withstand voltage protection circuit may include: a power supply node structured to receive the internal power supply voltage; and a zener diode connected between the power supply node and an output node of the gain stage.

In one embodiment, the first gain may be larger than 0.9.

In one embodiment, the voltage source may include: a voltage dividing circuit structured to divide the power supply voltage at a second voltage dividing ratio corresponding to the second gain; a linear regulator receiving an output voltage of the voltage dividing circuit as a reference voltage and generating the internal power supply voltage; a buffer structured to receive an output voltage of the voltage dividing circuit as a reference voltage and to output the reference voltage as the bias voltage V_{FIL}; and a clamp circuit structured to clamp a voltage of an output node of the voltage dividing circuit so as not to exceed a predetermined voltage.

In one embodiment, the audio amplifier circuit may be integrally integrated on one semiconductor substrate. The “integrally integrated” includes a case where all components of a circuit are formed on a semiconductor substrate and a case where main components of the circuit are integrally integrated, and some resistors, capacitors, and the like may be provided outside the semiconductor substrate for adjusting a circuit constant. By integrating the circuit on one chip, a circuit area can be reduced, and characteristics of circuit elements can be kept uniform.

### EMBODIMENTS

Hereinafter, preferred embodiments will be described with reference to the drawings. The same or equivalent components, members, and processes illustrated in the drawings will be denoted by the same reference numerals, and repeated description will be omitted as appropriate. Further, the embodiments do not limit the disclosure and the invention, but are exemplary, and all features and combinations thereof described in the embodiments are not necessarily essential to the disclosure and the invention.

In the present specification, a “state where a member A is connected to a member B” includes not only a case where the member A and the member B are directly connected physically but also a case where the member A and the member B are indirectly connected via another member that does not substantially affect an electrical connection state or does not impair a function and an effect provided by connection.

Similarly, a “state where a member C is connected (provided) between the members A and B” includes not only a case where the members A and C or the members B and C are directly connected but also a case where the members A and C or the members B and C are indirectly connected via another member that does not substantially affect an electrical connection state or does not impair a function and an effect provided by connection.

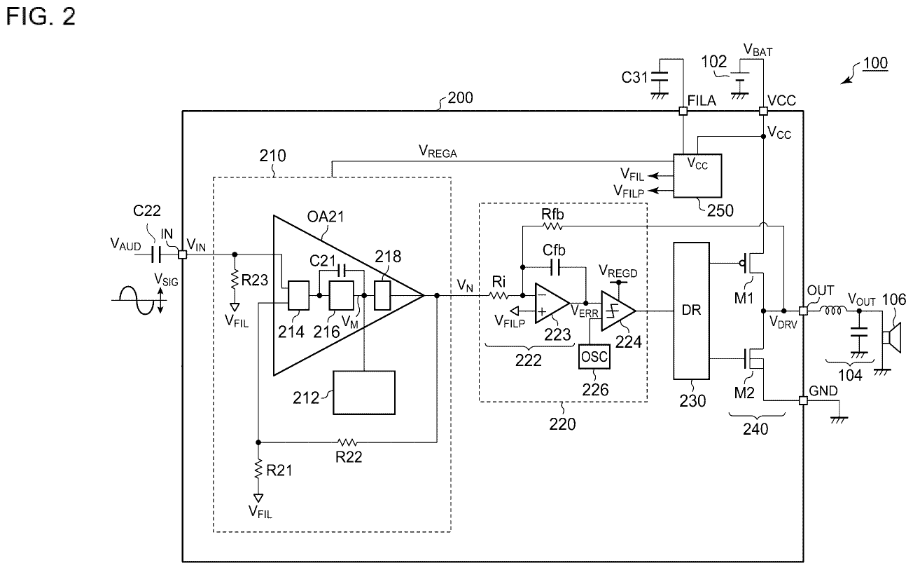

FIG. 2 is a circuit diagram of an in-vehicle audio system 100 including an audio amplifier circuit 200 according to a first embodiment. The in-vehicle audio system 100 includes an in-vehicle battery (hereinafter, simply referred to as the battery) 102, a filter 104, a speaker 106, and an audio amplifier circuit 200.

The battery 102 generates a rated battery voltage V_{BAT} of 12 V. The audio amplifier circuit 200 is a functional integrated circuit (IC) integrated on one semiconductor substrate, and the battery voltage V_{BAT} is supplied to the audio amplifier circuit 200 as a power supply voltage V_{CC}. The audio amplifier circuit 200 receives an input audio signal V_{AUD} from a sound source (not illustrated), amplifies the input audio signal V_{AUD}, and drives the speaker 106 to be a load. In the present embodiment, the in-vehicle audio system 100 includes a single-ended circuit.

The audio amplifier circuit 200 receives the audio signal V_{AUD} from a sound source (not illustrated) at an input terminal IN via a coupling capacitor C22. In addition, the speaker 106 is connected to an output terminal OUT of the audio amplifier circuit 200 via the filter 104.

The audio amplifier circuit 200 is a class-D amplifier (switching amplifier) and generates a pulse drive signal having a duty cycle according to the input audio signal V_{AUD}. A high frequency component of the pulse drive signal VDRV is removed by the filter 104, and an analog audio signal V_{OUT} in an audio band is supplied to the speaker 106.

A power supply terminal V_{CC} of the audio amplifier circuit 200 is connected to the battery 102 and receives the power supply voltage V_{CC}. An external capacitor C31 is connected to a capacitor connection terminal FILA. The pulse drive signal VDRV has an amplitude equal to the power supply voltage V_{CC}.

The audio amplifier circuit 200 includes an input gain circuit 210, a pulse width modulation (PWM) circuit 220, a driver circuit 230, an output stage 240, and a voltage source 250.

The power supply node V_{CC} of the voltage source 250 is supplied with the power supply voltage V_{CC}. The voltage source 250 generates an internal power supply voltage V_{REGA} obtained by multiplying the power supply voltage V_{CC} by a first gain K₁ and a bias voltage V_{FIL} obtained by multiplying the power supply voltage V_{CC} by a second gain K2. Further, the voltage source 250 generates a bias voltage V_{FILP} obtained by multiplying the power supply voltage V_{CC} by a third gain K₃. For example, the first gain K₁ is 0.9 or more, and specifically, in a case of V_{CC}=14 V, K₁=13/14 can be set such that V_{REGA}=13 V is obtained.

The internal power supply voltage V_{REGA} is supplied to the power supply node V_{CC} of the input gain circuit 210, and the bias voltage V_{FIL} is input as a reference voltage. The input gain circuit 210 amplifies an analog audio signal V_{AUD} with reference to the bias voltage V_{FIL}. When an alternating current (AC) component of the analog audio signal V_{AUD} is written as V_{SIG}, an input signal V_{IN} of the input terminal IN is represented by the following Formula.

$${V}_{IN} = {V}_{FIL} + {V}_{SIG}$$

When the gain of the input gain circuit 210 is set to g₁, an output signal V_{N} of the input gain circuit 210 is represented by the following Formula.

$${V}_{N} = {g}_{1} \times {V}_{SIG} + {V}_{FIL}$$

The input gain circuit 210 includes resistors R21 to R23, an operational amplifier OA21, and a withstand voltage protection circuit 212. The gain g₁ of the input gain circuit 210 is g₁=(R21+R22)/R21.

The operational amplifier OA21 includes an input stage 214, a gain stage 216, an output stage 218, and a phase compensation capacitor C21. The phase compensation capacitor C21 is connected between the input and output of the gain stage 216. As configurations of the input stage 214, the gain stage 216, and the output stage 218, known technologies may be used, and the configurations are not particularly limited. The output stage 218 may be omitted.

The phase compensation capacitor C21 has a withstand voltage Vbd determined by a device structure and a semiconductor manufacturing process. The withstand voltage protection circuit 212 is connected to the output node of the gain stage 216, and clamps an output voltage V_{M} of the gain stage 216 at a predetermined clamp level V_{CL} such that a voltage across the phase compensation capacitor C21 does not exceed a predetermined threshold voltage V_{TH}. The predetermined threshold voltage V_{TH} is determined according to the withstand voltage Vbd of the phase compensation capacitor C21.

The PWM circuit 220 is a feedback type pulse modulator. A power supply node of the PWM circuit 220 is supplied with the internal power supply voltage V_{REGA} from the voltage source 250. In addition, the reference voltage V_{FILP} is input from the voltage source 250 to the PWM circuit 220.

The PWM circuit 220 generates a pulse signal S_{PWM} having a pulse width according to the output signal V_{N} of the input gain circuit 210. The PWM circuit 220 includes an integrator 222, a comparator 224, and an oscillator 226.

The integrator 222 receives the output signal V_{N} of the input gain circuit 210 of the previous stage and the drive pulse VDRV. The integrator 222 includes an operational amplifier 223, resistors Ri and Rfb, and a capacitor Cfb. The reference voltage V_{FILP} is input to a non-inverting input node of the integrator 222. The integrator 222 functions as an error amplifier, and amplifies an error between an integrated value (smoothed voltage) of voltages obtained by internally dividing the two voltages V_{N} and VDRV by the resistors Ri and Rf and the reference voltage V_{FILP}.

The comparator 224 compares an output voltage V_{ERR} of the integrator 222 with a periodic signal of a triangular wave generated by the oscillator 226 and generates the pulse signal S_{PWM}. A power supply voltage of the comparator 224 is an internal power supply voltage V_{REGD}. Therefore, a high level of the pulse signal S_{PWM} is V_{REGD}, and a low level of the pulse signal S_{PWM} is 0 V. For example, V_{REGD}=5 V is satisfied.

The output stage 240 includes a high-side transistor M1 and a low-side transistor M2. The high-side transistor M1 is connected between the power supply terminal V_{CC} and the output terminal OUT, and the low-side transistor M2 is connected between the output terminal OUT and the ground terminal GND.

The driver circuit 230 drives the output stage 240 such that the high-side transistor M1 and the low-side transistor M2 are complementarily turned on according to the pulse signal S_{PWM}.

The above is the configuration of the audio amplifier circuit 200.

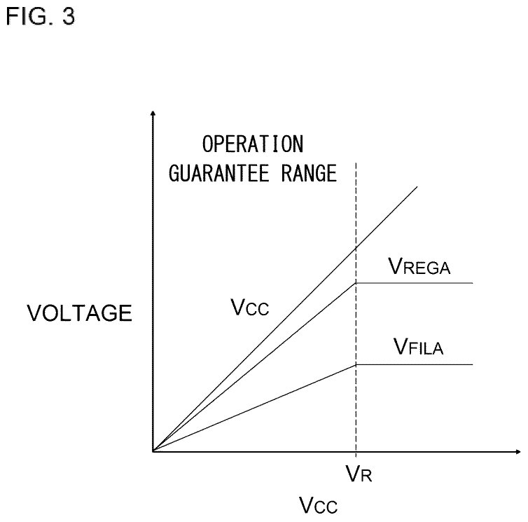

FIG. 3 is a diagram illustrating input/output characteristics of the voltage source 250. An operation guarantee range of the audio amplifier circuit 200 is V_{CC}<V_{R}. The internal power supply voltage V_{REGA} and the bias voltage V_{FIL} are proportional to the power supply voltage V_{CC} within a range of V_{CC}<V_{R}. In a range of V_{CC}>V_{R}, the internal power supply voltage V_{REGA} and the bias voltage V_{FIL} are clamped.

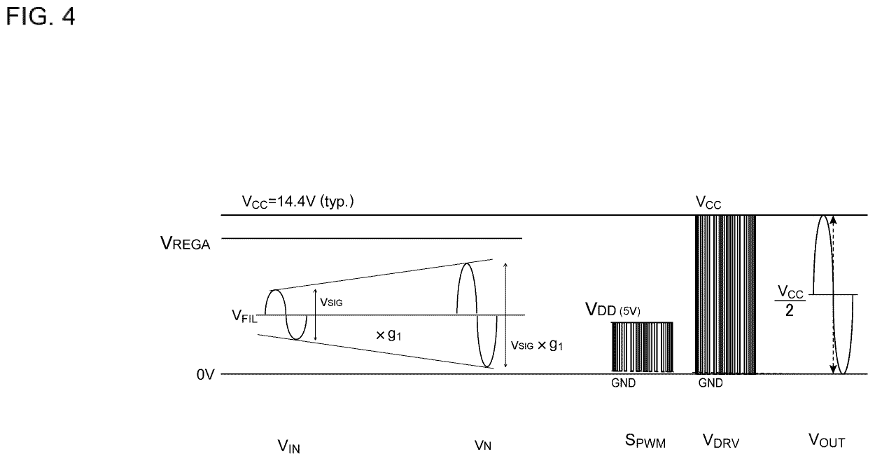

FIG. 4 is a diagram illustrating a level diagram of the in-vehicle audio system 100 of FIG. 2. FIG. 4 illustrates the voltage V_{IN} of the input terminal IN, the output signal V_{N} of the input gain circuit 210, the PWM signal S_{PWM}, the drive signal VDRV, and the output voltage V_{OUT}.

The input voltage V_{IN} of the input gain circuit 210 is a signal obtained by superimposing the AC component V_{SIG} of the audio signal V_{AUD} on the bias level V_{FIL}. The bias levels of the input signal V_{IN} and the output signal V_{N} of the input gain circuit 210 are V_{FIL}, and the amplitude of the audio signal is amplified by the gain g₁. In general, the bias level V_{FIL} is a midpoint voltage V_{REGA}/2 of the internal power supply voltage V_{REGA}. However, in the present embodiment, the bias level V_{FIL} is V_{FIL}≠V_{REGA}/2. The bias level V_{FIL} will be described later.

The PWM signal S_{PWM} is a pulse signal with the internal power supply voltage V_{REGD} as a high level and the ground voltage GND (0 V) as a low level, and a duty cycle thereof depends on the voltage V_{N}. Specifically, in the case of V_{N}=V_{FIL}, the duty cycle of the PWM signal S_{PWM} is 50%. The integrator 222 is an inverting amplifier. For this reason, when V_{N} becomes lower than V_{FIL}, the duty cycle of the PWM signal S_{PWM} becomes higher than 50%, and when V_{N} becomes higher than V_{FIL}, the duty cycle becomes lower than 50%.

The drive signal VDRV is a pulse signal with the power supply voltage V_{CC} as a high level and the ground voltage GND (0 V) as a low level. The duty cycle of the drive signal VDRV is equal to the duty cycle of the PWM signal S_{PWM}.

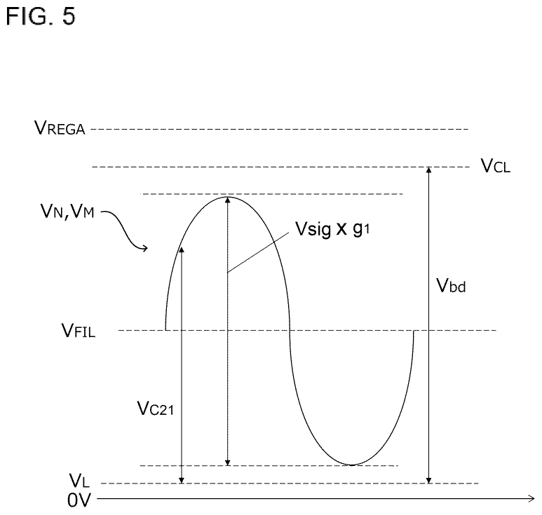

Next, a relation among the bias voltage V_{FIL}, the withstand voltage of the phase compensation capacitor C21, and the clamp voltage of the withstand voltage protection circuit 212 will be described. FIG. 5 is a diagram illustrating a level diagram of the input gain circuit 210 in the first embodiment.

FIG. 5 illustrates the output voltage V_{M} of the gain stage 216 of the input gain circuit 210. Since the voltage gain of the output stage 218 of the input gain circuit 210 is substantially 1, the output voltage V_{M} of the gain stage 216 is considered to be equal to the output voltage V_{N} of the input gain circuit 210. Since the voltage V_{N} is an AC signal centered on the bias voltage V_{FIL}, the output voltage V_{M} of the gain stage 216 is also an AC signal centered on the bias voltage V_{FIL}. In FIG. 5, it is assumed that Vsig is an assumed maximum value.

As described above, the phase compensation capacitor C21 is connected between the input and output terminals of the gain stage 216. The input voltage of the gain stage 216, that is, one end of the phase compensation capacitor C21 may be considered as a substantially constant level. When the input stage 214 is a P-type input, the input voltage of the gain stage 216 is a voltage near 0 V (actually, 0.5 to 1 V), and when the input stage 214 is an N-type input, the input voltage of the gain stage 216 is a voltage near the internal power supply voltage V_{REGA} (actually, V_{REGA}-0.5V to V_{REGA}-1V). In the first embodiment, the input voltage of the gain stage 216 is assumed to be a voltage V_{L} close to 0 V. A case where the input voltage of the gain stage 216 is close to V_{REGA} will be described later in a second embodiment.

On the other hand, the voltage at the other end of the phase compensation capacitor C21 is V_{M}. Therefore, a voltage V_{C21} across the phase compensation capacitor C21 is V_{M}−V_{L}. Considering the withstand voltage Vbd of the phase compensation capacitor C21, if a peak of the voltage V_{M} is lower than V_{L}+Vbd, the reliability of the phase compensation capacitor C21 is guaranteed. Therefore, the clamp level V_{CL} of the withstand voltage protection circuit 212 is determined to satisfy V_{CL}≤V_{L}+Vbd.

In order to take a maximum amplitude in a range of 0 V to V_{CL}, V_{FIL}≈V_{CL}/2 may be determined. Note that V_{FIL} does not need to be completely matched with V_{CL}/2 and may be shifted to the high potential side or the low potential side. For example, by using a parameter α that takes a range of 0.9 to 1.1, V_{FIL}=α×V_{CL} may be determined. In other words, the bias voltage V_{FIL} may be determined to satisfy V_{CL}/2×0.9≤V_{FIL}≤V_{CL}/2×1.1.

In the case of α=1, that is, in the case of V_{FIL}=V_{CL}/2, the maximum amplitude of the voltage V_{N} is V_{CL}. Therefore, the gain g₁ of the input gain circuit 210 may be determined to satisfy V_{SIG}×g₁≤V_{CL}.

In the case of α<1, that is, in the case of V_{FIL}<V_{CL}/2, the maximum amplitude α×V_{CL} of the voltage V_{N} is obtained. Therefore, the gain g₁ of the input gain circuit 210 may be determined to satisfy V_{SIG}×g₁≤α×V_{CL}.

In the case of α>1, that is, in the case of V_{FIL}>V_{CL}/2, the maximum amplitude (2−α)×V_{CL} of the voltage V_{N} is obtained. Therefore, the gain g₁ of the input gain circuit 210 may be determined to satisfy V_{SIG}×g₁≤(2−α)×V_{CL}.

The above is the configuration of the audio amplifier circuit 200.

According to the audio amplifier circuit 200, when the input audio signal V_{AUD} having the large amplitude is generated, the voltage V_{C21} across the phase compensation capacitor C21 can be protected so as not to exceed the withstand voltage.

Further, since the gain g₁ of the input gain circuit 210 can be determined to be large, the gain g₂ of the PWM circuit 220 can be reduced. As a result, an amplification factor of the thermal noise generated by the resistors Ri and Rfb of the PWM circuit 220 can be reduced, and a noise characteristic of the entire audio amplifier circuit 200 can be improved.

The present disclosure extends to various apparatuses and methods understood as the block diagram or the circuit diagram of FIG. 2 or derived from the above description and is not limited to a specific configuration. Hereinafter, more specific configuration examples and examples will be described in order not to narrow the scope of the present disclosure but to help understanding of the present disclosure and the essence and operation of the present disclosure and to clarify them.

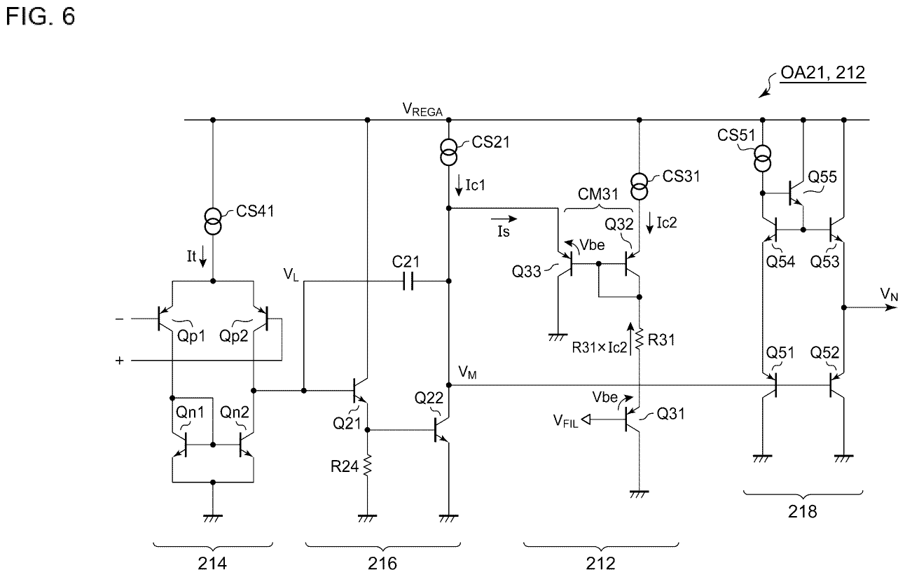

FIG. 6 is a circuit diagram illustrating a first configuration example of the operational amplifier OA21 and the withstand voltage protection circuit 212. The input stage 214 of the operational amplifier OA21 can include a P-type input differential amplifier. PNP bipolar transistors Qp1 and Qp2 form a differential pair. NPN bipolar transistors Qn1 and Qn2 are current mirror circuit loads. A tail current source CS41 generates a tail current It.

The gain stage 216 includes transistors Q21 and Q22, a current source CS21, and a resistor R24. The transistor Q21 and the resistor R24 are a source follower circuit. The current source CS21 generates a constant current Ic1.

The output stage 218 includes a current source CS51 and transistors Q51 to Q55.

When the output voltage V_{M} of the gain stage 216 exceeds a clamp level V_{CL} obtained by level-shifting the bias voltage V_{FIL} to a high potential side by a predetermined voltage width ΔV, the withstand voltage protection circuit 212 sinks a current Is from the output node of the gain stage 216.

$${V}_{C L} = {V}_{FIL} + Δ V$$

The withstand voltage protection circuit 212 is connected to the output node of the gain stage 216. The withstand voltage protection circuit 212 includes a current source CS31, a resistor R31, a transistor Q31, and a current mirror circuit CM31. The current source CS31 generates a constant current Ic2. The transistor Q31 is a PNP bipolar transistor and has a control electrode (base) receiving the bias voltage V_{FIL} and a first electrode (collector) connected to a ground. The resistor R31 is connected to a second electrode (emitter) of the transistor Q31.

The current mirror circuit CM31 includes transistors Q32 and Q33. The transistor Q32 on the input side of the current mirror circuit CM31 is inserted between the resistor R31 and the current source CS31. The output transistor Q33 of the current mirror circuit CM31 is connected to the output node of the gain stage 216.

In the withstand voltage protection circuit 212, the voltage width ΔV becomes ΔV=2× Vbe+R31×Ic2, and the clamp level V_{CL} becomes V_{CL}=V_{FIL}+2×Vbe+R31×Ic2. Vbe is a base-emitter voltage of the transistors Q31 and Q33, and R31×Ic2 is a voltage drop across the resistor R31.

When the output voltage V_{M} of the gain stage 216 increases to the clamp level V_{CL}=V_{FIL}+2×Vbe+R31×Ic2, the current flowing through the transistor Q22 decreases, and the voltage V_{M} is clamped.

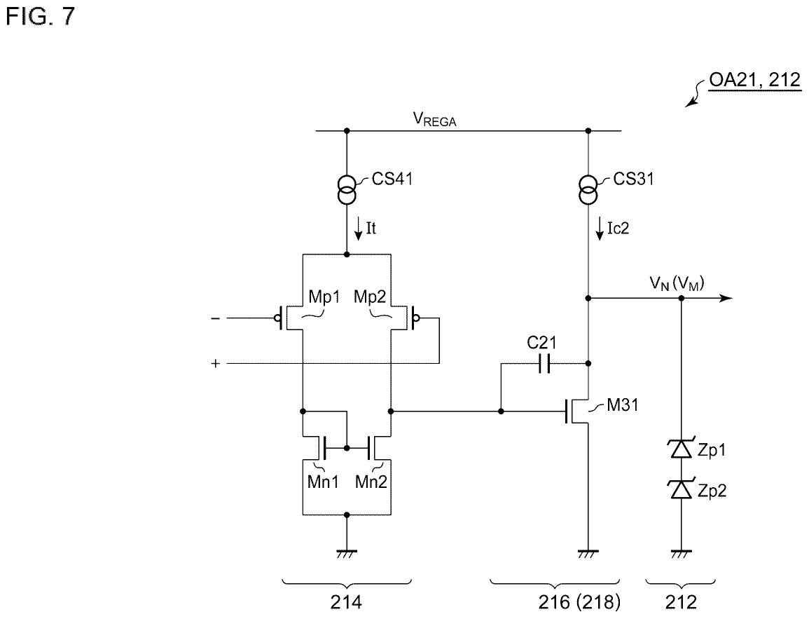

FIG. 7 is a circuit diagram illustrating a second configuration example of the operational amplifier OA21 and the withstand voltage protection circuit 212. In the operational amplifier OA21, the output stage 218 is omitted, and the gain stage 216 also functions as the output stage 218. The input stage 214 has a configuration in which the bipolar transistor of FIG. 6 is replaced with a metal oxide semiconductor field effect transistor (MOSFET), and includes transistors Mp1, Mp2, Mn1, and Mn2, and a tail current source CS41.

The gain stage 216 includes a transistor M31 and a current source CS31. The transistor M31 is an N-channel MOSFET, and its source is connected to a ground. The current source CS31 supplies a constant current to the transistor M31. The phase compensation capacitor C21 is connected between the input and output of the gain stage 216, that is, between a gate and a drain of the transistor M31.

The withstand voltage protection circuit 212 includes a plurality of zener diodes ZD1 and ZD2 connected in series. When the zener diode of the zener diode is set to Vz and the number of stages is set to n (in this example, 2), the clamp level V_{CL} becomes V_{CL}=n×Vz.

In the configuration of FIG. 6, the bipolar transistor may be replaced with an FET. In the configuration of FIG. 7, the FET may be replaced with a bipolar transistor.

### Second Embodiment

In a second embodiment, it is assumed that an input stage 214 of an operational amplifier OA21 is an N-type input. When the input stage 214 is an N-type input, an input voltage of a gain stage 216 becomes a voltage V_{H} near an internal power supply voltage V_{REGA} (actually, V_{REGA}−0.5V to V_{REGA}−1V).

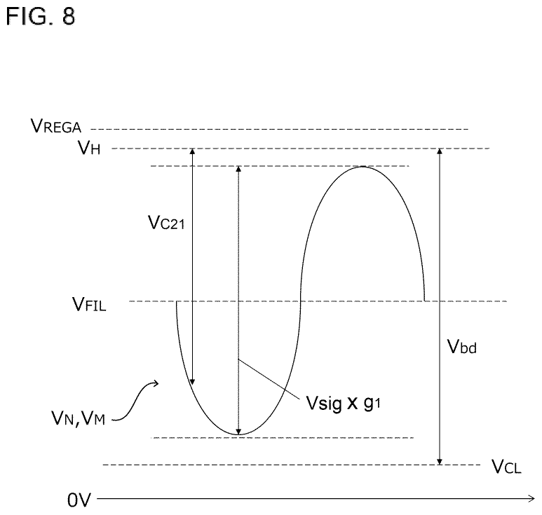

FIG. 8 is a diagram illustrating a level diagram of an input gain circuit 210 in the second embodiment. FIG. 8 illustrates a case where the input voltage of the gain stage 216, that is, a voltage at one end of a phase compensation capacitor C21 is the high voltage V_{H} close to the internal power supply voltage V_{REGA}. It is assumed that an output voltage V_{M} of the gain stage 216 is an AC signal centered on a bias voltage V_{FIL}.

A voltage V_{C21} across the phase compensation capacitor C21 becomes V_{H}−V_{N}. Considering a withstand voltage Vbd of the phase compensation capacitor C21, if the bottom of the voltage V_{N} is higher than V_{H}−Vbd, the reliability of the phase compensation capacitor C21 is guaranteed. Therefore, a clamp level V_{CL} of a withstand voltage protection circuit 212 is determined to satisfy V_{CL}≥ V_{H}-Vbd.

In order to take a maximum amplitude in a range of 0 V to V_{CL}, V_{FIL}≈V_{REGA}−V_{CL}/2 may be determined. Note that V_{FIL} does not need to be completely matched with V_{REGA}−V_{CL}/2 and may be shifted to the high potential side or the low potential side. For example, by using a parameter β that takes a range of 0.9 to 1.1, V_{FIL}=V_{REGA}−β×V_{CL} may be determined. In other words, the bias voltage V_{FIL} may be determined to satisfy V_{REGA}−V_{CL}/2×1.1≤ V_{FIL}≤ V_{REGA}−V_{CL}/2×0.9.

In the case of β=1, that is, in the case of V_{FIL}=V_{REGA}−V_{CL}/2, the maximum amplitude of the voltage V_{N} becomes V_{REGA}−V_{CL}. Therefore, a gain g₁ of the input gain circuit 210 may be determined to satisfy V_{SIG}×g₁≤V_{REGA}−V_{CL}.

In the case of β<1, that is, in the case of V_{FIL}>V_{REGA}−V_{CL}/2, the maximum amplitude of the voltage V_{N} becomes (V_{REGA}−V_{FIL})×2=2α·V_{CL}. Therefore, the gain g₁ of the input gain circuit 210 may be determined to satisfy V_{SIG}×g₁≤2α·V_{CL}.

In the case of β>1, that is, in the case of V_{FIL}<V_{REGA}−V_{CL}/2, the maximum amplitude of the voltage V_{N} becomes V_{FIL}×2=2×(V_{REGA}−+×V_{CL}).

The gain g₁ of the input gain circuit 210 may be determined to satisfy V_{SIG}×g₁≤2×(V_{REGA}−α×V_{CL}).

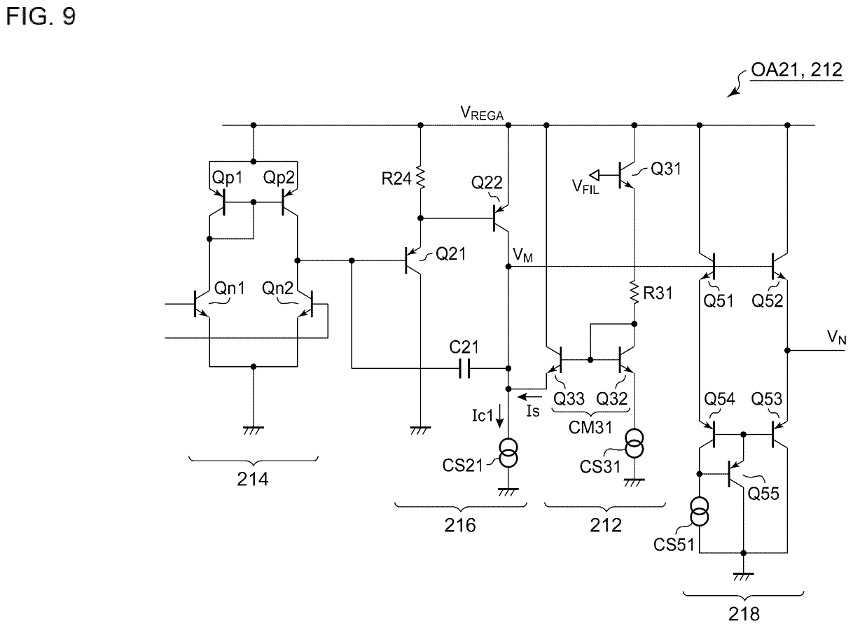

FIG. 9 is a circuit diagram illustrating a third configuration example of the operational amplifier OA21 and the withstand voltage protection circuit 212. The operational amplifier OA21 has an N-type input. This is obtained by vertically inverting the configuration of FIG. 6 and replacing the polarity of the transistor.

The configuration of the withstand voltage protection circuit 212 is also obtained by vertically inverting the withstand voltage protection circuit 212 of FIG. 7. When the output voltage V_{M} of the gain stage 216 falls below the clamp level V_{CL} obtained by level-shifting the bias voltage V_{FIL} to the low potential side by a predetermined voltage width ΔV, the withstand voltage protection circuit 212 sources a current to the output node of the gain stage 216.

$${V}_{CL} = {V}_{FIL} - Δ V$$

$$Δ V = 2 \times V b e + R 31 \times I c 2$$

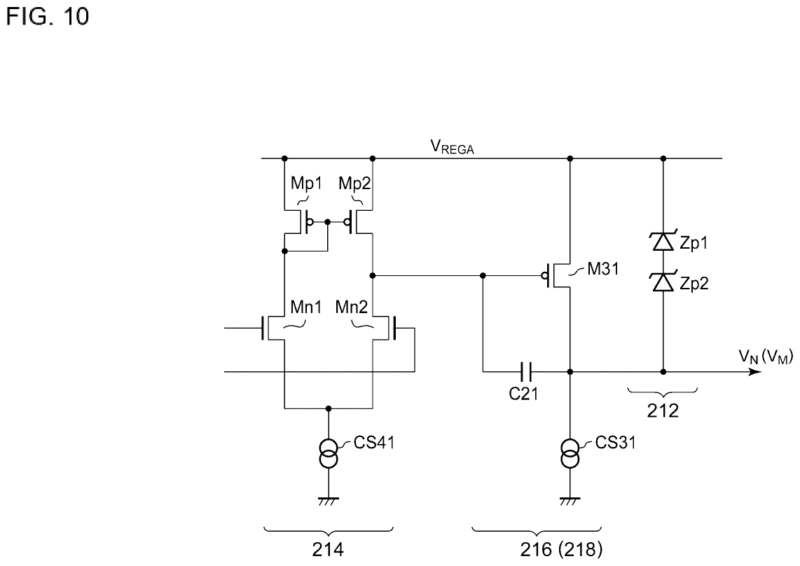

FIG. 10 is a circuit diagram illustrating a fourth configuration example of the operational amplifier OA21 and the withstand voltage protection circuit 212. FIG. 10 is obtained by vertically inverting the configuration of FIG. 7. The withstand voltage protection circuit 212 clamps the output voltage V_{M} such that the output voltage V_{M} of the gain stage 216 does not fall below the clamp level V_{CL} obtained by shifting the internal power supply voltage V_{REGA} by a predetermined width ΔV in a low voltage direction.

$${V}_{CL} = {V}_{R E G A} - n \times V z$$

Next, a configuration example of a voltage source 250 will be described.

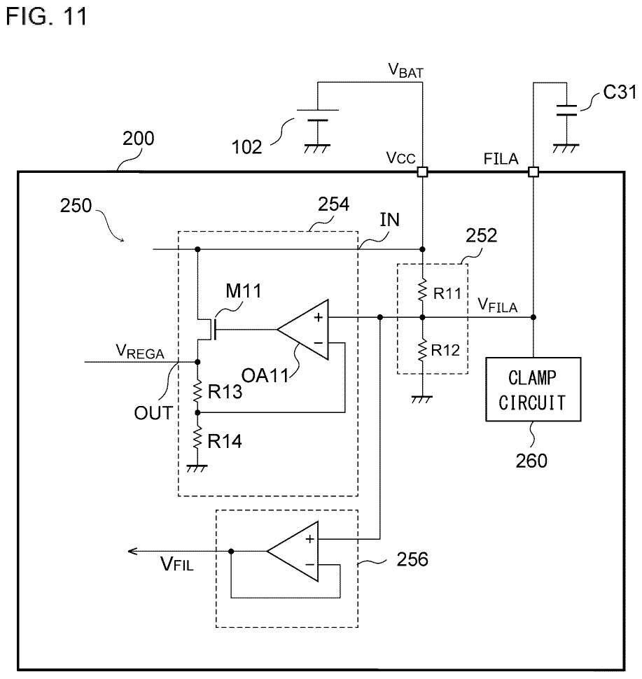

FIG. 11 is a circuit diagram illustrating the configuration example of the voltage source 250. The voltage source 250 includes a voltage dividing circuit 252, a linear regulator 254, a buffer 256, and a clamp circuit 260. The voltage dividing circuit 252 divides a power supply voltage V_{CC}. An output node of the voltage dividing circuit 252 is connected to a capacitor connection terminal FILA. The voltage dividing circuit 252 includes resistors R11 and R12. A voltage V_{FILA} at the output node of the voltage dividing circuit 252 becomes V_{FILA}=V_{CC}×R12/(R11+R12). The buffer 256 outputs the voltage V_{FILA} as the bias voltage V_{FIL}. That is, the gain g₂ becomes a voltage dividing ratio R12/(R11+R12) of the voltage dividing circuit 252.

$${V}_{F I L} = {V}_{F I L A} = {g}_{2} \times {V}_{C C}$$

$${g}_{2} = R 12 / ( R 11 + R 12 )$$

The linear regulator 254 receives the output voltage V_{FILA} of the voltage dividing circuit 252 as a reference voltage and generates an internal power supply voltage V_{REGA}. The linear regulator 254 includes an operational amplifier OA11, resistors R13 and R14, and a transistor M13. The input/output characteristics of the linear regulator 254 become V_{REGA}=(R13×R14)/R14×V_{FILA}=(R13×R14)/R14×g₂× V_{CC}. Therefore, g₁=(R13× R14)/R14×g₂ may be satisfied.

The clamp circuit 260 clamps the voltage V_{FILA} of the FILA terminal so as not to exceed a predetermined level g₂× V_{R}. As a result, the input/output characteristics of FIG. 3 can be realized.

### Modifications

The embodiments described above are merely examples, and it is understood by those skilled in the art that various modifications can be made in the combination of the respective components or the respective processing processes. Hereinafter, the modifications will be described.

In the embodiments, the audio amplifier circuit 200 is configured as a single-ended audio amplifier circuit, but the audio amplifier circuit 200 may be configured as a differential audio amplifier circuit.

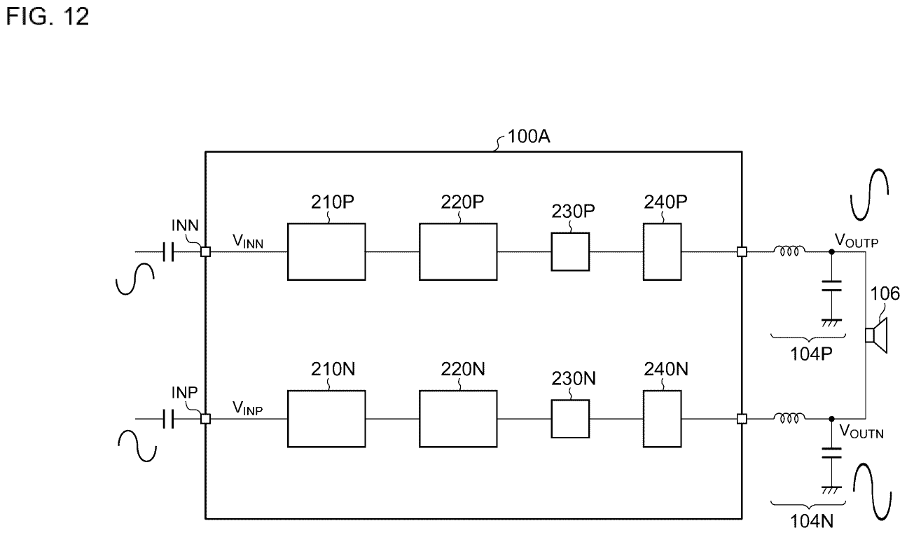

FIG. 12 is a circuit diagram of an audio amplifier circuit 200A according to a modification. Differential audio signals VINN and VINP are input to the audio amplifier circuit 200A. An in-vehicle audio system 100A is of a fully differential type, and the input gain circuit 210, the PWM circuit 220, the driver circuit 230, and the output stage 240 are provided on the P side and the N side. Since the polarity of the signal is inverted in the PWM circuit 220, an N-polarity signal is input to a block corresponding to the P-side output OUTP, and a P-polarity signal is input to a block corresponding to the N-side output OUTN.

### Supplementary Note

The following technologies are disclosed herein.

### Item 1

An audio amplifier circuit including:
a power supply terminal receiving a power supply voltage;
a voltage source having a power supply node to which the power supply voltage is supplied and generating an internal power supply voltage obtained by multiplying the power supply voltage by a first gain and a bias voltage V_{FIL} obtained by multiplying the power supply voltage by a second gain;
an input gain circuit having a power supply node to which the internal power supply voltage is supplied and amplifying an analog audio signal with reference to the bias voltage V_{FIL};
a pulse modulator having a power supply node to which the internal power supply voltage is supplied and generating a pulse signal having a pulse width according to an output signal of the input gain circuit; and
a driver amplifying the pulse signal, wherein
the input gain circuit includes
an operational amplifier having an input stage and a gain stage,
a phase compensation capacitor connected to the gain stage, and
a withstand voltage protection circuit structured to clamp an output voltage of the gain stage to a predetermined clamp voltage V_{CL}.

### Item 2

The audio amplifier circuit according to item 1, wherein
the input stage has a P-type input, and
the withstand voltage protection circuit clamps the output voltage of the gain stage so as not to exceed the clamp voltage V_{CL}.

### Item 3

The audio amplifier circuit according to item 2, wherein
when α is set to a constant satisfying 0.9≤α≤1.1, V_{FIL}=α×V_{CL} is satisfied.

### Item 4

The audio amplifier circuit according to item 2 or 3, wherein
the clamp voltage V_{CL} is a voltage obtained by level-shifting the bias voltage V_{FIL} to a high potential side, and
the withstand voltage protection circuit sinks a current from an output node of the gain stage when the output voltage of the gain stage exceeds the clamp voltage V_{CL}.

### Item 5

The audio amplifier circuit according to item 2 or 3, wherein
the withstand voltage protection circuit includes:
a current source;
a first transistor having a control electrode receiving the bias voltage V_{FIL} and a first electrode connected to a ground;
a resistor connected to a second electrode of the first transistor; and
a current mirror circuit including an input transistor and an output transistor, in which the input transistor is inserted between the resistor and the current source, and the output transistor is connected to an output node of the gain stage.

### Item 6

The audio amplifier circuit according to item 2 or 3, wherein
the withstand voltage protection circuit includes a zener diode connected between a ground line and an output node of the gain stage.

### Item 7

The audio amplifier circuit according to item 1, wherein
the input stage has an N-type input; and
the withstand voltage protection circuit clamps the output voltage of the gain stage so as not to fall below a clamp voltage.

### Item 8

The audio amplifier circuit according to item 7, wherein
when β is set to a constant satisfying 0.9≤β≤1.1, V_{FIL}=V_{REGA}−B×V_{CL} is satisfied.

### Item 9

The audio amplifier circuit according to item 7 or 8, wherein
the clamp voltage V_{CL} is a voltage obtained by level-shifting the bias voltage V_{FIL} to a low potential side, and
the withstand voltage protection circuit sources a current to an output node of the gain stage, when the output voltage of the gain stage falls below the clamp voltage V_{CL}.

### Item 10

The audio amplifier circuit according to item 7 or 8, wherein
the withstand voltage protection circuit includes
a power supply node structured to receive the internal power supply voltage,
a current source,
a first transistor having a control electrode receiving the bias voltage V_{FIL} and a first electrode connected to the power supply node,
a resistor connected to a second electrode of the first transistor, and
a current mirror circuit including an input transistor and an output transistor, in which the input transistor is inserted between the resistor and the current source, and the output transistor is connected to an output node of the gain stage.

### Item 11

The audio amplifier circuit according to item 7 or 8, wherein
the withstand voltage protection circuit includes:
a power supply node structured to receive the internal power supply voltage; and
a zener diode connected between the power supply node and an output node of the gain stage.

### Item 12

The audio amplifier circuit according to any one of items 1 to 5, wherein the first gain is larger than 0.9.

### Item 13

The audio amplifier circuit according to any one of items 1 to 12, wherein
the voltage source includes
a voltage dividing circuit structured to divide the power supply voltage at a second voltage dividing ratio corresponding to the second gain,
a linear regulator receiving an output voltage of the voltage dividing circuit as a reference voltage and generating the internal power supply voltage,
a buffer structured to receive an output voltage of the voltage dividing circuit as a reference voltage and to output the reference voltage as the bias voltage V_{FIL}, and
a clamp circuit structured to clamp a voltage of an output node of the voltage dividing circuit so as not to exceed a predetermined voltage.

### Item 14

The audio amplifier circuit according to any one of items 1 to 13, wherein the audio amplifier circuit is integrally integrated on one semiconductor substrate.

### Item 15

An in-vehicle electronic device including the audio amplifier circuit according to any one of items 1 to 14.

What is claimed is:

1. An audio amplifier circuit comprising:
a power supply terminal structured to receive a power supply voltage;
a voltage source having a power supply node to which the power supply voltage is supplied and structured to generate an internal power supply voltage obtained by multiplying the power supply voltage by a first gain and a bias voltage V_{FIL} obtained by multiplying the power supply voltage by a second gain;
an input gain circuit having a power supply node to which the internal power supply voltage is supplied and structured to amplify an analog audio signal with reference to the bias voltage V_{FIL};
a pulse modulator having a power supply node to which the internal power supply voltage is supplied and structured to generate a pulse signal having a pulse width according to an output signal of the input gain circuit; and
a driver structured to amplify the pulse signal, wherein
the input gain circuit includes
an operational amplifier having an input stage and a gain stage,
a phase compensation capacitor connected to the gain stage, and
a withstand voltage protection circuit structured to clamp an output voltage of the gain stage to a predetermined clamp voltage V_{CL}.

2. The audio amplifier circuit according to claim 1, wherein
the input stage has a P-type input, and
the withstand voltage protection circuit clamps the output voltage of the gain stage so as not to exceed the clamp voltage V_{CL}.

3. The audio amplifier circuit according to claim 2, wherein
when a is set to a constant satisfying 0.9≤α≤1.1, V_{FIL}=α×V_{CL} is satisfied.

4. The audio amplifier circuit according to claim 2, wherein
the clamp voltage V_{CL} is a voltage obtained by level-shifting the bias voltage V_{FIL} to a high potential side, and
the withstand voltage protection circuit sinks a current from an output node of the gain stage when the output voltage of the gain stage exceeds the clamp voltage V_{CL}.

5. The audio amplifier circuit according to claim 2, wherein
the withstand voltage protection circuit includes
a current source,
a first transistor having a control electrode receiving the bias voltage V_{FIL} and a first electrode connected to a ground,
a resistor connected to a second electrode of the first transistor, and
a current mirror circuit including an input transistor and an output transistor, in which the input transistor is inserted between the resistor and the current source, and the output transistor is connected to an output node of the gain stage.

6. The audio amplifier circuit according to claim 2, wherein the withstand voltage protection circuit includes a zener diode connected between a ground line and an output node of the gain stage.

7. The audio amplifier circuit according to claim 1, wherein
the input stage has an N-type input; and
the withstand voltage protection circuit clamps the output voltage of the gain stage so as not to fall below a clamp voltage.

8. The audio amplifier circuit according to claim 7, wherein
when β is set to a constant satisfying 0.9≤β≤1.1, V_{FIL}=V_{REGA}−β×V_{CL} is satisfied.

9. The audio amplifier circuit according to claim 7, wherein
the clamp voltage V_{CL} is a voltage obtained by level-shifting the bias voltage V_{FIL} to a low potential side, and
the withstand voltage protection circuit
sources a current to an output node of the gain stage, when the output voltage of the gain stage falls below the clamp voltage V_{CL}.

10. The audio amplifier circuit according to claim 7, wherein
the withstand voltage protection circuit includes
a power supply node structured to receive the internal power supply voltage,
a current source,
a first transistor having a control electrode receiving the bias voltage V_{FIL} and a first electrode connected to the power supply node,
a resistor connected to a second electrode of the first transistor, and
a current mirror circuit including an input transistor and an output transistor, in which the input transistor is inserted between the resistor and the current source, and the output transistor is connected to an output node of the gain stage.

11. The audio amplifier circuit according to claim 7, wherein
the withstand voltage protection circuit includes
a power supply node structured to receive the internal power supply voltage, and
a zener diode connected between the power supply node and an output node of the gain stage.

12. The audio amplifier circuit according to claim 1, wherein
the first gain is larger than 0.9.

13. The audio amplifier circuit according to claim 1, wherein
the voltage source includes
a voltage dividing circuit structured to divide the power supply voltage at a second voltage dividing ratio corresponding to the second gain,
a linear regulator receiving an output voltage of the voltage dividing circuit as a reference voltage and generating the internal power supply voltage,
a buffer structured to receive an output voltage of the voltage dividing circuit as a reference voltage and to output the reference voltage as the bias voltage V_{FIL}, and
a clamp circuit structured to clamp a voltage of an output node of the voltage dividing circuit so as not to exceed a predetermined voltage.

14. The audio amplifier circuit according to claim 1, wherein
the audio amplifier circuit is integrally integrated on one semiconductor substrate.

15. An in-vehicle electronic device comprising the audio amplifier circuit according to claim 1.
